(19) United States
(12) Patent Application Publication
(10) Pub. No.: US 2021/0057461 A1
(43) Pub. Date: Feb. 25, 2021

(54) ELECTRONIC DEVICE AND METHOD FOR MANUFACTURING THE SAME

(71) Applicant: InnoLux Corporation, Miao-Li County (TW)

(72) Inventors: Yu-Chia HUANG, Miao-Li County (TW); Kuan-Feng LEE, Miao-Li County (TW); Tsung-Han TSAI, Miao-Li County (TW); Chu-Hong LAI, Miao-Li County (TW); Yu-Chih TSENG, Miao-Li County (TW)

(21) Appl. No.: 16/941,880

(22) Filed: Jul. 29, 2020

(30) Foreign Application Priority Data
Aug. 22, 2019 (CN) 201910779018.9

(51) Int. Cl. H01L 27/12; G02F 1/1333; H01L 51/00

(52) U.S. Cl. CPC H01L 27/1262; H01L 51/0097; H01L 27/1218; G02F 1/133305

(57) ABSTRACT

A manufacturing method of an electronic device is provided. The method includes providing a dummy substrate. The method includes forming a conductive pattern on the dummy substrate. The method includes forming a flexible layer to cover the conductive pattern. Additionally, the method includes forming a circuit layer on the flexible layer. The method includes removing the dummy substrate.

### CROSS REFERENCE TO RELATED APPLICATIONS

This application claims priority of China Patent Application No. 201910779018.9 filed on Aug. 22, 2019, the entirety of which are incorporated by reference herein.

### BACKGROUND OF THE DISCLOSURE

### Field of the Invention

The disclosure relates to an electronic device and a manufacturing method of the same, and it particularly relates to an electronic device having a conductive pattern and a manufacturing method of the same.

### Description of the Related Art

As digital technology has advanced, electronic devices have been widely used in daily life, and the electronic devices have been developed to be light, thin, small, and fashionable.

Electronic devices may include a conductive pattern having multiple functions. Since the current technology used in the formation of such a conductive pattern limits the applications for electronic devices, the industry still needs a new manufacturing method to form an electronic device having a conductive pattern.

### BRIEF SUMMARY OF THE DISCLOSURE

Some embodiments of the present disclosure provide a manufacturing method of an electronic device. The method includes providing a dummy substrate. The method includes forming a conductive pattern on the dummy substrate. The method includes forming a flexible layer to cover the conductive pattern. Additionally, the method includes forming a circuit layer on the flexible layer. The method includes removing the dummy substrate.

Other embodiments of the present disclosure provide an electronic device. The electronic device includes a flexible layer having a first surface and a second surface opposed to the first surface. The electronic device includes a circuit layer on the first surface of the flexible layer. The electronic device includes a conductive pattern, wherein the flexible layer is between the circuit layer and the conductive pattern.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIGS. 1A-1G illustrate cross-sectional views showing a manufacturing method of an electronic device according to some embodiments of the present disclosure.

FIGS. 2A-2C illustrate cross-sectional views showing a manufacturing method of an electronic device according to some embodiments of the present disclosure.

FIGS. 3A-3C illustrate cross-sectional views showing a manufacturing method of an electronic device according to some embodiments of the present disclosure.

FIGS. 4A-4D illustrate cross-sectional views showing a manufacturing method of an electronic device according to some embodiments of the present disclosure.

FIGS. 5A-5B illustrate cross-sectional views showing two stages of a manufacturing method of an electronic device according to some embodiments of the present disclosure.

FIGS. 6A-6B illustrate cross-sectional views of an electronic device according to some embodiments of the present disclosure.

FIG. 7 illustrates a three-dimensional view of a conductive pattern according to some embodiments of the present disclosure.

FIG. 8 illustrates a cross-sectional view of an electronic device according to some embodiments of the present disclosure.

FIG. 9 illustrates a cross-sectional view of an electronic device according to some embodiments of the present disclosure.

FIG. 10 illustrates a cross-sectional view of an electronic device according to some embodiments of the present disclosure.

FIG. 11 illustrates a cross-sectional view of an electronic device according to some embodiments of the present disclosure.

FIG. 12 illustrates a cross-sectional view of an electronic device according to some embodiments of the present disclosure.

FIG. 13 illustrates a cross-sectional view of an electronic device according to some embodiments of the present disclosure.

FIG. 14 illustrates a top view of a conductive pattern according to some embodiments of the present disclosure.

FIGS. 15A-15C illustrate top views of a conductive pattern according to some embodiments of the present disclosure.

FIG. 16 illustrates a cross-sectional view of an electronic device according to some embodiments of the present disclosure.

FIG. 17 illustrates a cross-sectional view of an electronic device according to some embodiments of the present disclosure.

FIG. 18 illustrates a cross-sectional view of an electronic device according to some embodiments of the present disclosure.

### DETAILED DESCRIPTION

Hereinafter, an electronic device and a manufacturing method of the same of some embodiments of the present disclosure will be described in detail. It should be understood that different embodiments are provided below to implement the different aspects of the present disclosure. The particular elements and configurations described below are merely exemplary but not limiting. In addition, in the various embodiments, repeated reference numerals or signs may be used only to describe some embodiments simply and clearly, and do not represent any connection between the various embodiments and/or structures discussed. Furthermore, when a first layer is disposed on or located on or on a second layer, the situation where the first layer is directly in contact with the second layer is included. Alternatively, it is also possible to have one or more layers of other materials interposed, in which case there may be no direct contact between the first layer and the second layer.

Herein, the terms “about”, “around” and “substantially” typically mean +/−20% of the stated value or range, typically +/−10% of the stated value or range, typically +/−5% of the stated value or range, typically +/−3% of the stated value or range, typically +/−2% of the stated value or range, typically +/−1% of the stated value or range, and typically +/−0.5% of the stated value or range. The stated number of the present disclosure is an approximate number. Namely, the meaning of “about”, “around” and “substantially” may be implied if there is no specific description of “about”, “around” and “substantially”.

It should be understood that although the terms “first”, “second”, “third” etc. may be used herein to describe various elements, components, regions, layers, and/or portions, these elements, components, regions, layers, and/or portions should not be limited by these terms. These terms are only used to distinguish one element, component, region, layer, and/or portion from another element, component, region, layer and/or portion. Thus, a first element, component, region, layer, or portion discussed below could be termed a second element, component, region, layer, or portion without departing from the teachings of the present disclosure.

Unless defined otherwise, all the terms used herein (including technical and scientific terms) have the same meaning as commonly understood by one of ordinary skill in the art to which this disclosure belongs. It should be appreciated that the term, which is defined in a commonly used dictionary, should be interpreted as having a meaning that conforms to the related skills and the background or the context of the present disclosure, and should not be interpreted in an idealized or overly formal manner unless so defined in the embodiments of the present disclosure.

Some embodiments of the present disclosure can be understood in connection with the accompanying drawings, which are to be considered part of the entire written description. It should be understood that the drawings of the embodiments of the present disclosure are not drawn to scale. The shapes and thicknesses of elements (or layers) of the embodiments may be exaggerated in the drawings to clearly show the features. In addition, the structures and devices in the drawings are schematically illustrated in order to clearly illustrate the features of the embodiments of the present disclosure.

In some embodiments of the present disclosure, relative terms such as “lower,” “upper,” “horizontal,” “vertical”, “below”, “above”, “top” and “bottom” should be construed to refer to the orientation as described in the paragraph or as shown in the drawing under discussion. These relative terms are only for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

It should be noted that the term “substrate” or “panel” hereinafter may include elements formed on the substrate (such as transistor elements or circuits) and the layers overlaying the substrate, but in order to simplify the drawings here, a flat substrate is shown.

The electronic device according to some embodiments of the present disclosure may include a display device, an illumination device, an antenna device, a sensing device, a splicing device, other suitable devices, or a combination thereof, but is not limited thereto. The electronic device can be a bendable or flexible device. The term “flexible electronic device” as mentioned in some embodiments of the present disclosure means that the electronic device can be bent, folded, curled, flexed or the like along at least one bending axis, but is not limited thereto. According to some embodiments, the device may also be bent separately along more than two bending axes.

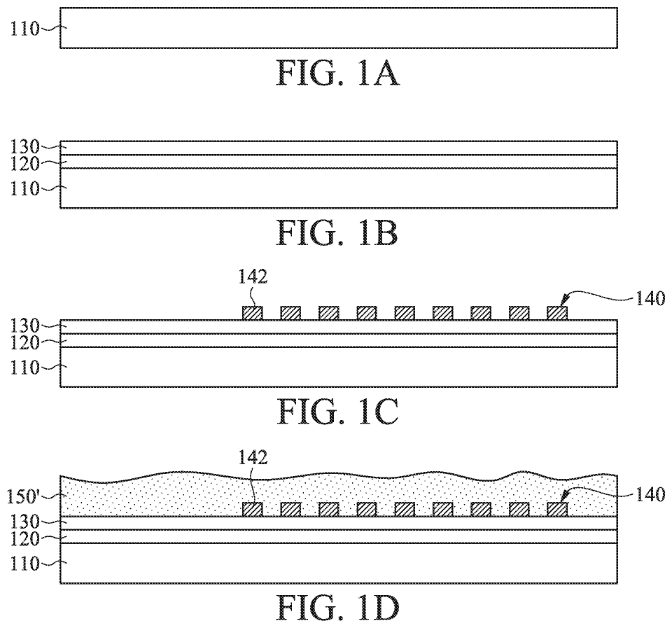

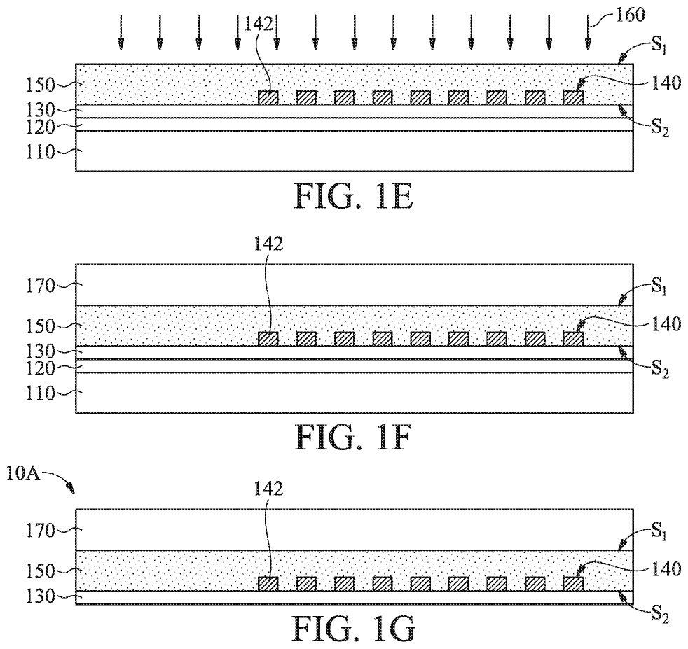

Refer to FIGS. 1A-1F, which illustrate cross-sectional views of a manufacturing method of an electronic device according to some embodiments of the present disclosure. As shown in FIG. 1A, first, a dummy substrate 110 is provided. In some embodiments, the dummy substrate 110 is disposed to temporarily carry the elements formed thereon and will be removed in subsequent processes. In some embodiments, the dummy substrate 110 can be a rigid substrate. The dummy substrate 110 may include glass, sapphire, ceramic, or other suitable materials, but is not limited thereto.

As shown in FIG. 1B, the peeling layer 120 and the protection layer 130 are sequentially formed on the dummy substrate 110. The material of the peeling layer 120 may include a metal such as chromium, nickel, cobalt or molybdenum; a metal oxide such as chromium oxide, nickel oxide, chromium phosphate or nickel phosphate; and an organic compound such as benzotriazole, a derivative thereof or a combination thereof, but is not limited thereto. The peeling layer 120 can provide sufficient adhesion to reduce the peeling of the protection layer 130 from the dummy substrate 110 and can be easily peeled off from the protection layer 130. The protection layer 130 includes silicon nitride, silicon oxide, silicon oxynitride or other suitable materials, but is not limited thereto. The protection layer 130 is disposed to protect a conductive pattern that is formed subsequently, and reduces the effect of an external force on the conductive pattern. In some embodiments, the peeling layer 120 and/or the protection layer 130 can be selectively formed. In some embodiments, the peeling layer 120 and/or the protection layer 130 are not formed.

As shown in FIG. 1C, a conductive pattern 140 is formed on the protection layer 130. The conductive pattern 140 includes a conductive material such as copper (Cu), nickel (Ni), gold (Au), titanium (Ti), aluminum (Al), chromium (Cr), palladium (Pt), silver (Ag), aluminum (Al), other metal materials, an alloy thereof or a combination thereof, but is not limited thereto. The conductive pattern 140 can perform a variety of functions (e.g. at least one of the functions of a light polarizing element, an antenna element, a touch sensing element and a fingerprint sensing element). In some embodiments, the conductive pattern 140 can be at least one of a light polarizing element, an antenna element, a touch sensing element, and a fingerprint sensing element. In some embodiments, the conductive pattern 140 can serve as a wire grid polarizer (WGP). For example, the conductive pattern 140 may let light having a first polarization direction (such as a p-wave) through and may reflect light having a second polarization direction (such as an s-wave) perpendicular to the first polarization direction. The conductive pattern 140 may be formed of a plurality of long strips of metal wires 142, but is not limited thereto.

In some embodiments, the conductive pattern 140 may be formed by a Nanoimprint Lithography (NIL), an inkjet printing technique, a micro electro mechanical system or the like, but is not limited thereto. In some embodiments, the process of the Nanoimprint Lithography includes disposing a metal material on the protection layer 130; forming a photoresist on the metal material; using a patterned imprinter to imprint the photoresist to pattern the photoresist; and etching the metal material by the patterned photoresist to form a conductive pattern.

In some embodiments, as shown in FIG. 1D, a liquid polymer layer 150′ is disposed on the protection layer 130 and the conductive pattern 140 and covers the conductive pattern 140. The polymer layer 150′ can fill the space between two adjacent metal lines 142. In addition, since the polymer layer 150′ has a stronger adhesion and is in a liquid state, the upper surface of the polymer layer 150′ is not flat. The material of the polymer layer 150′ may include polyimide (PI), polyethylene terephthalate (PET), polycarbonate (PC), polyether sulfones (PES), polybutylene terephthalate (PBT), polyethylene naphthalate (PEN) or polyarylate (PAR), other suitable materials or a combination thereof, but is not limited thereto.

As shown in FIG. 1E, a curing process 160 is performed to cure the polymer layer 150′ to form a flexible layer 150 covering the conductive pattern 140. The curing process 160 includes irradiation of ultraviolet rays, heating, other methods, or a combination thereof, but is not limited thereto. In some embodiments, the conductive pattern 140 is embedded within the flexible layer 150. The flexible layer 150 has a first surface S1 and a second surface S2 opposite thereto. The second surface S2 may be adjacent to the protection layer 130. In some embodiments, the conductive pattern 140 is embedded into the flexible layer 150 from the second surface S2. In other words, the conductive pattern 140 is disposed between the flexible layer 150 and the protection layer 130.

In some embodiments, after the flexible layer 150 is formed, a planarization process can be performed. Since a portion of the flexible layer 150 is formed on the conductive pattern 140 and a portion of the flexible layer 150 is formed over the protective layer 130, the surface of the flexible layer 150 is uneven The first surface S1 of the flexible layer 150 can be made a flatter surface by a planarization process.

As shown in FIG. 1F, a circuit layer 170 is formed on the first surface S1 of the flexible layer 150. In some embodiments, circuit layer 170 includes a plurality of active elements and/or passive elements. The active elements may include a thin film transistor. The thin film transistors may include a switching transistor, a driver transistor, a reset transistor, or other thin film transistors. The passive elements may include capacitors, inductors, or other passive elements, but are not limited thereto. In some embodiments, the active elements of the circuit layer 170 can be electrically connected to the conductive pattern 140. In some embodiments, the active elements of the circuit layer 170 are not electrically connected to the conductive pattern 140. As shown in FIG. 1G, the dummy substrate 110 and the peeling layer 120 are removed to form the electronic device 10A. In some embodiments, the dummy substrate 110 and the peeling layer 120 may be removed by a laser lift off (LLF) process or other suitable processes. The electronic device 10A includes the conductive pattern 140 that can serve as a wire grid polarizer, and the conductive pattern 140 is embedded in the bendable flexible layer 150. Thereby, the conductive pattern 140 can be applied to the flexible electronic device 10A. In some embodiments, when the conductive pattern 140 that uses a metal material is formed on a flexible substrate by a Nanoimprint Lithography technology, there may be a problem that the metal material is not easily formed. In this embodiment, the rigid dummy substrate 110 is provided first, the conductive pattern 140 is formed thereon, and the flexible layer 150 is formed on the conductive pattern 140, thereby reducing the problems caused by using the Nanoimprint Lithography to form the conductive pattern 140 directly on a flexible substrate.

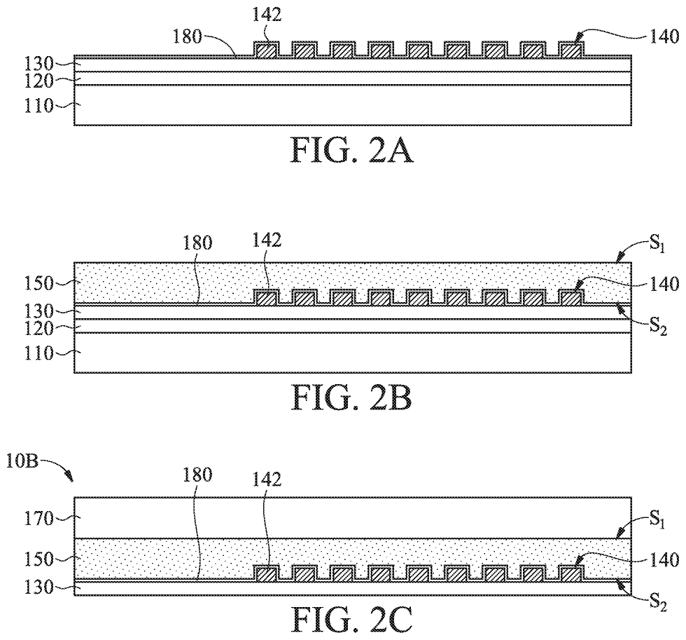

Refer to FIGS. 2A-2C, which illustrate cross-sectional views showing a manufacturing method of an electronic device 10B according to some embodiments of the present disclosure. In some embodiments, an interlayer 180 may be disposed on the structure shown in FIG. 1C described above to form a structure as shown in FIG. 2A. The material of the interlayer 180 may include a fluid material such as an organic layer and/or an inorganic layer, but is not limited thereto. The interlayer 180 may be formed by processes including a chemical vapor deposition process, a physical vapor deposition process, an atomic layer deposition process, a spin coating process, a Sol-Gel process, or other suitable processes, but not limited thereto. As shown in FIG. 2A, the interlayer 180 can be conformally formed on the conductive pattern 140 and fills the space between the two adjacent metal lines 142. In some embodiments, the interlayer 180 covers the upper surface and side surfaces of the metal lines 142.

As shown in FIG. 2B, the flexible layer 150 is formed on the interlayer 180 and the conductive pattern 140. The process of forming the flexible layer 150 may be the same as or similar to the processes as shown in FIGS. 1D to 1E, and the details are not described herein again. The flexible layer 150 can fill the space between the two adjacent metal wires 142. It should be noted that the “to fill the space between . . . adjacent . . . ” mentioned in some embodiments of the present disclosure may refer to the case where the space is completely filled or the space is partially filled.

As shown in FIG. 2C, the circuit layer 170 is formed on the flexible layer 150, and the dummy substrate 110 and the peeling layer 120 are removed to form the electronic device 10B. The foregoing processes may be the same as or similar to the processes as shown in FIGS. 1F-1G, and the details are not described herein again. In this embodiment, the formation of the interlayer 180 with a better fluidity on the conductive pattern 140 allows the polymer layer 150′ having a larger viscosity coefficient to more easily fill the space between the two adjacent metal lines 142, reducing the probability of the flexible layer 150 being peeled off from the conductive pattern 140.

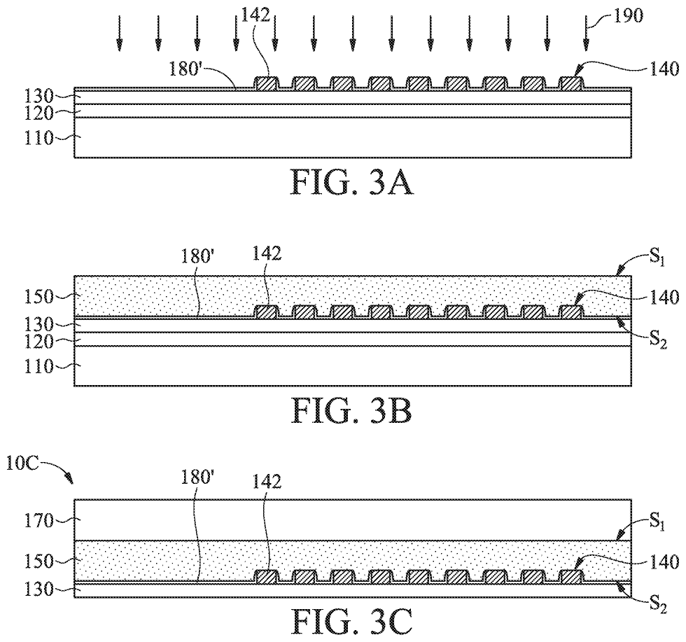

Refer to FIGS. 3A-3C, which illustrate cross-sectional views showing a manufacturing method of an electronic device 10C according to some embodiments of the present disclosure. In some embodiments, an etching process 190 can be performed on the structure as shown in FIG. 2A above, to remove a portion of the interlayer 180 to form the interlayer 180′. As shown in FIG. 3A, the interlayer 180′ does not cover the upper surface of the conductive pattern 140, but covering at least a portion of the side surface of the conductive pattern 140 and at least a portion of the upper surface of the protection layer 130. In other embodiments, the interlayer 180′ covers at least a portion of the side surface of the conductive pattern 140. In other embodiments, the interlayer 180′ covers at least a portion of the upper surface of the protection layer 130, but is not limited thereto.

As shown in FIG. 3B, the flexible layer 150 is formed on the interlayer 180′ and the conductive pattern 140. The processes of forming the flexible layer 150 may be the same as or similar to the processes as shown in FIGS. 1D to 1E, and the details are not described herein again. The flexible layer 150 can fill the space between the two adjacent metal wires 142.

As shown in FIG. 3C, the circuit layer 170 is formed on the flexible layer 150, and the dummy substrate 110 and the peeling layer 120 are removed to form the electronic device 10C. The foregoing processes may be the same as or similar to the processes shown in FIGS. 1F-1G, and the details are not described herein again. In this embodiment, forming the interlayer 180′ with a better fluidity on the conductive pattern 140 allows the polymer layer 150′ having a larger viscosity coefficient to more easily fill the space between the two adjacent metal lines 142, reducing the probability of the flexible layer 150 being peeled off from the conductive pattern 140.

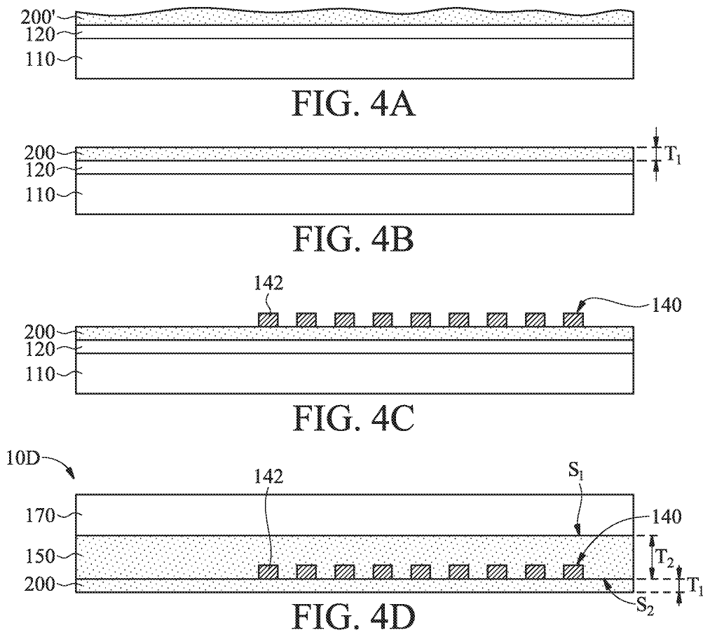

Refer to FIGS. 4A-4D, which illustrate cross-sectional views showing a manufacturing method of an electronic device 10D according to some embodiments of the present disclosure. As shown in FIG. 4A, in some embodiments, prior to forming the conductive pattern 140, a liquid polymer layer 200′ may be formed on the peeling layer 120 in place of the protection layer 130. In some embodiments, the material and processes of polymer layer 200′ may be the same as or similar to those of the polymer layer 150′. In some embodiments, the material and processes of polymer layer 200′ may be different from those of the polymer layer 150′, but is not limited thereto. As shown in FIG. 4B, a curing process is performed to cure the polymer layer 200′ to form a flexible layer 200. The curing process may include irradiation of ultraviolet rays, heating, other methods, or a combination thereof, but is not limited thereto. The flexible layer 200 has a thickness T1, which may be the maximum thickness of the flexible layer 200 in the normal direction. In some embodiments, the thickness T1 ranges between about 3 μm (micrometers) to 5 μm (3 μm≤thickness T1≤5 μm).

As shown in FIG. 4C, the conductive pattern 140 is formed on the flexible layer 200. Referring to FIG. 4D, the flexible layer 150 and the circuit layer 170 are formed, and the dummy substrate 110 and the peeling layer 120 are removed to form the electronic device 10D. The foregoing processes may be the same as or similar to the processes as shown in FIGS. 1D-1G, and the details are not described herein again. The flexible layer 150 has a thickness T2 which may be the maximum thickness of the flexible layer 150 in the normal direction. In some embodiments, the thickness T2 ranges between about 15 μm to 20 μm (15 μm≤thickness T2≤20 μm). In some embodiments, the thickness T1 is less than the thickness T2. Since the thickness T1 is thinner, the conductive pattern 140 can be formed on the flexible layer 200 by a Nanoimprint Lithography, which can reduce the problem that the metal material cannot be formed on the flexible substrate. In this embodiment, replacing the protection layer 130 with the flexible layer 200 can enhance the ability of the electronic device 10D to flex.

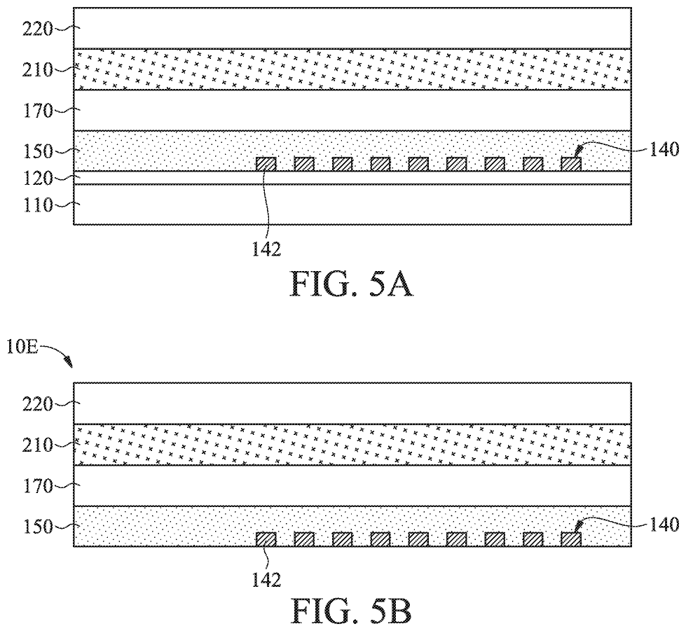

Refer to FIGS. 5A-5B, which illustrate cross-sectional views showing a manufacturing method of an electronic device 10E according to some embodiments of the present disclosure. As shown in FIG. 5A, in some embodiments, a medium layer 210 and an another substrate 220 may be formed on the circuit layer 170. In some embodiments, the medium layer 210 may be a liquid-crystal layer, and the liquid-crystal molecules included in the medium layer 210 may be arranged in a nematic, smectic, or cholesteric manner, but the present disclosure is not limited to thereto. In some embodiments, the medium layer 210 can be sealed between the circuit layer 170 and the another substrate 220. In other embodiments, the medium layer 210 may include a light-emitting diode (LED), an organic light-emitting diode (OLED), a quantum dot (QD), a fluorescence, a phosphor, other suitable materials or a combination thereof, but is not limited thereto. The light-emitting diode may include, for example, a sub-millimeter light-emitting diode (mini LED), a micro light-emitting diode (micro LED) or a quantum dot light-emitting diode (QLED, QDLED), a fluorescence, a phosphor, other suitable materials or a combination thereof, but is not limited to them. In other embodiments, some layers or structures may be added or removed depending on the type of the media layer that is selected, which will not be described herein.

The another substrate 220 may contain various active elements and/or passive elements depending on the use of the electronic device. The active elements may include a thin film transistor or other elements. The thin film transistors may include a switching transistor, a driver transistor, a reset transistor, or other thin film transistors. The passive elements include capacitors, inductors, or other passive elements, but are not limited thereto. In some embodiments, the flexible layer 150 may have a curved shape and the another substrate 220 may have the same or similar shape as the flexible layer 150 does.

As shown in FIG. 5B, the dummy substrate 110 and the peeling layer 120 are removed to form the electronic device 10E. In some embodiments, the dummy substrate 110 and the peeling layer 120 may be removed by a laser lift-off process or other suitable processes. In some embodiments, the dummy substrate 110 and the peeling layer 120 may be removed before the medium layer 210 and/or the another substrate 220 are disposed, but the present disclosure is not limited thereto. In this embodiment, since the electronic device 10E includes the medium layer 210, the electronic device 10E can serve as a display device. In some embodiments, replacing the polarizing plate made of polyimide with the conductive pattern 140 can reduce the thickness of the electronic device and also reduce manufacturing time and cost.

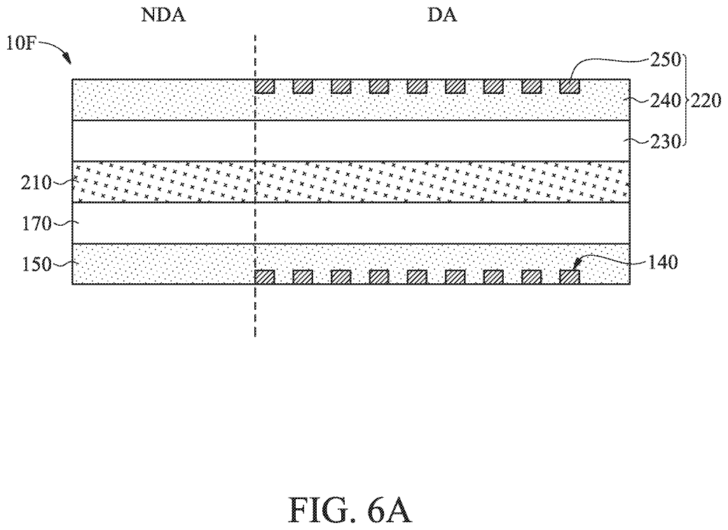

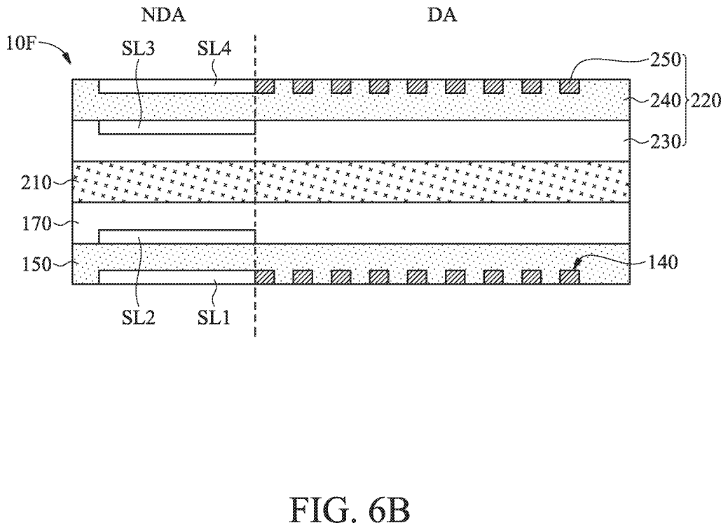

Refer to FIG. 6A, which illustrates a cross-sectional view of an electronic device 10F according to some embodiments of the present disclosure. As shown in FIG. 6A, the another substrate 220 of the electronic device 10F may further include a circuit layer 230, a flexible layer 240, and a conductive pattern 250. The circuit layer 230 is disposed on the medium layer 210, and the flexible layer 240 is disposed on the circuit layer 230. In some embodiments, the conductive pattern 250 can be embedded within the flexible layer 240. In some embodiments, the conductive pattern 140 and the conductive pattern 250 may be embedded in the flexible layer 150 and the flexible layer 240, respectively. In some embodiments, the circuit layer 230 may include a plurality of active elements and/or passive elements. The active elements include a thin film transistor. The thin film transistors may include a switching transistor, a driver transistor, a reset transistor, or other thin film transistors. The passive elements include capacitors, inductors, or other passive elements, but are not limited thereto. In some embodiments, the circuit layer 170 and the circuit layer 230 may include a plurality of active elements and/or passive elements. The active elements include a thin film transistor. The thin film transistors may include a switching transistor, a driver transistor, a reset transistor, or other thin film transistors. The passive elements include capacitors, inductors, or other passive elements, but are not limited thereto. In some embodiments, as shown in FIG. 6B, the electronic device 10F includes a display area DA and a non-display area NDA, and the circuit layer 170 and/or the circuit layer 230 includes a switching transistor corresponding to the display area DA, but is not limited thereto. In some embodiments, the circuit layer 170 and/or the circuit layer 230 includes a driver transistor corresponding to the non-display area NDA, but is not limited thereto. In some embodiments, the circuit layer 170 and/or the circuit layer 230 includes a switching transistor corresponding to the display area DA and a driver transistor corresponding to the non-display area NDA as well, but is not limited thereto. In some embodiments, the conductive pattern 140 and/or the conductive pattern 250 has a light-penetrable region corresponding to the display area DA of the circuit layer 170 and/or the circuit layer 230, and is not limited thereto. In some embodiments, the conductive pattern 140 and/or the conductive pattern 250 includes a first shielding layer SL1 and/or a fourth shielding layer SL4 which are areas that can reflect light and/or shield light corresponding to the non-display area NDA of the circuit layer 170 and/or the circuit layer 230, but is not limited thereto. In some embodiments, the non-display area NDA of the circuit layer 170 and/or the circuit layer 230 includes a second shielding layer SL2 and/or a third shielding layer SL3 which are areas that can reflect light and/or shield light, but is not limited thereto. In some embodiments, the electronic device 10F includes a single layer of a shielding layer, such as the first shielding layer SL1, the second shielding layer SL2, the third shielding layer SL3, or the fourth shielding layer SL4, but is not limited thereto. In some embodiments, the electronic device 10F includes a plurality of layers of shielding layers, such as any combination of the first shielding layer SL1, the second shielding layer SL2, the third shielding layer SL3, or the fourth shielding layer SL4. As shown in FIGS. 6A and 6B, the flexible layer 240 includes a flexible material. In some embodiments, the material and formation method of the flexible layer 240 may be the same as or similar to those of the flexible layer 150, which will not be repeated herein. In some embodiments, the material and formation method of the flexible layer 240 can be different from those of the flexible layer 150. In some embodiments, the conductive pattern 250 may be a conductive material. In some embodiments, the conductive pattern 250 may include at least one of a light polarizing element, an antenna element, a touch sensing element, and a fingerprint sensing element or other sensing elements. In some embodiments, the conductive pattern 250 can serve as a wire grid polarizer. In some embodiments, the conductive pattern 250 may be formed by a Nanoimprint Lithography, an inkjet printing technique, a Micro Electro Mechanical Systems, or the like, but is not limited thereto. In some embodiments, the material and formation method of the conductive pattern 250 may be the same as or different from those of the conductive pattern 140. In some embodiments, the material and formation method of circuit layer 230 may be the same or different from those of the circuit layer 170.

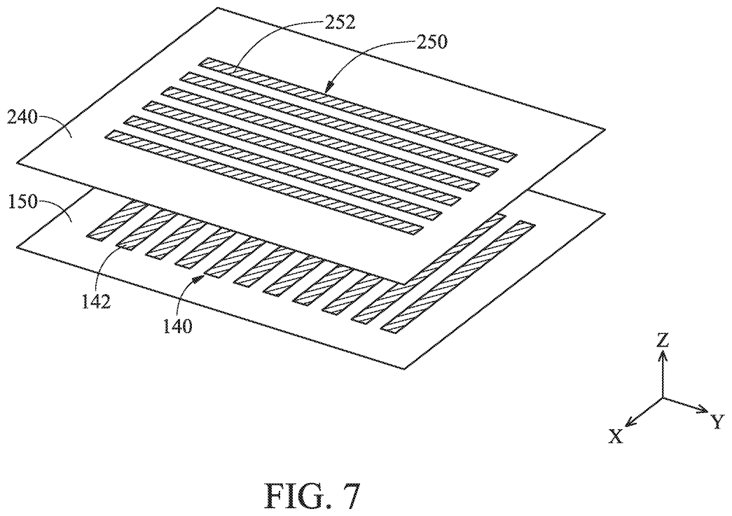

Refer to FIG. 7, which illustrates the arrangement relationship of the conductive pattern 140 and the conductive pattern 250 in FIGS. 6A and 6B. The conductive pattern 140 includes a plurality of metal lines 142 extending in a first direction, for example, extending in the X direction. The conductive pattern 250 includes a plurality of metal lines 252 extending in a second direction, for example, extending in the Y direction. In some embodiments, after the extending direction of the metal line 142 and the extending direction of the metal line 252 are projected into the XY plane, the formed angle may be between 80° and 100° (80°≤angle≤100°). In this embodiment, when the arrangement direction of the conductive pattern 140 and the conductive pattern 250 is in the foregoing range, the electronic device 10F can serve as a normally black type electronic device.

In some embodiments, the conductive pattern 140 may be disposed on the upper substrate and the lower substrate of the electronic device 10F. In the present specification, the upper substrate and the lower substrate may be defined by a distance from a viewer. For example, the viewer is closer to the substrate and farther from the lower substrate. The upper substrate and the lower substrate may also be defined by their distances from the backlight module. For example, the backlight module is farther from the upper substrate and closer to the lower substrate. The lower substrate may include the conductive pattern 140, the flexible layer 150 and the circuit layer 170. The upper substrate may include the conductive pattern 250, the flexible layer 240 and the circuit layer 230.

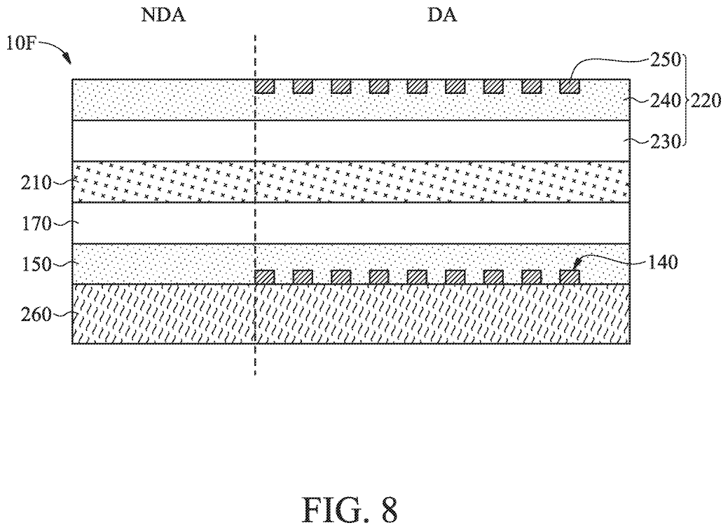

Refer to FIG. 8, which illustrates a cross-sectional view of an electronic device 10G according to some embodiments of the present disclosure. The electronic device 10G includes a backlight module 260. The backlight module 260 may be disposed on the second surface S2 of the flexible layer 150.

In some embodiments, the backlight module 260 can be a direct back-light or an edge LED back-light. In some embodiments, the backlight module 260 may include a light-emitting diode, an organic light-emitting diode, a quantum dot, a fluorescence, a phosphor, other suitable materials, or a combination thereof, but is not limited thereto. The light-emitting diode may include, for example, a sub-millimeter light-emitting diode, a micro light-emitting diode, a quantum dot light-emitting diode, a fluorescence, a phosphor, other suitable materials or a combination thereof, but is not limited to them.

The light-emitting diode may include a semiconductor layer and a light-emitting layer. The semiconductor layer may be doped InₓAl_{y}Ga_{(1-x-y)}N, where 0≤x≤1, 0≤y≤1 and 0≤(x+y)≤1, such as doped GaN, InN, AlN, InₓGa₍₁₋ₓ₎N, AlₓIn_{y}Ga_{(1-x-y)}N or the like, where 0≤x≤1, 0≤y≤1 and 0≤(x+y)≤1. The light-emitting layer may include a homojunction, a heterojunction, a single-quantum well (SQW), a multiple-quantum well (MQW) or the like. In an embodiment, the light-emitting layer may include other commonly used materials, such as AlₓIn_{y}Ga_{(1-x-y)}N, but the disclosure is not limited thereto.

In some embodiments, the backlight module 260 may include an organic light-emitting diode. The organic light-emitting diode may include an upper electrode, a lower electrode, and an organic light-emitting layer disposed between the upper electrode and the lower electrode. The organic light-emitting layer may include an organic film. In addition, the backlight module 260 may also include a light-guiding plate, a reflection layer, a diffusion plate or other elements, but is not limited thereto.

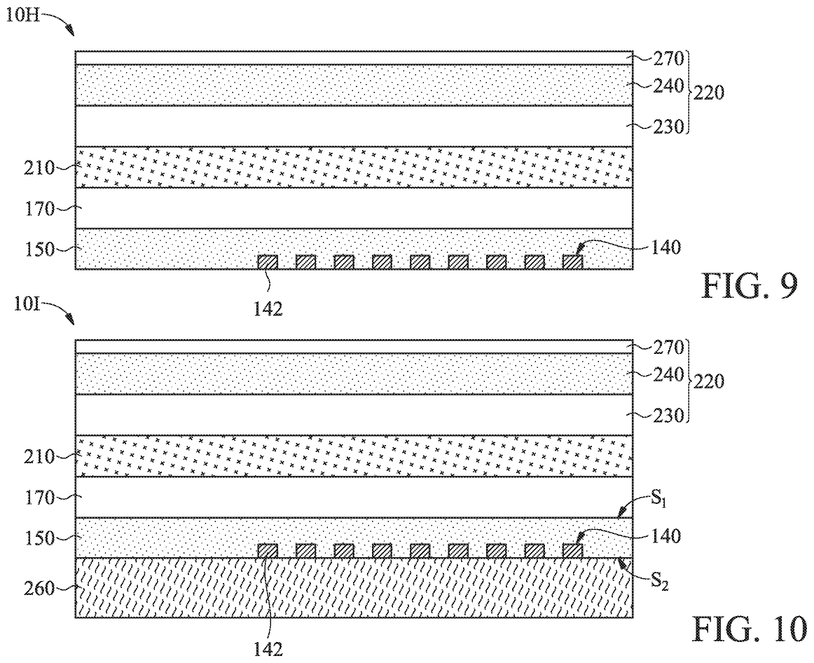

Refer to FIG. 9, which illustrates a cross-sectional view of an electronic device 10H according to some embodiments of the present disclosure. The electronic device 10H includes a polarizer 270 disposed on the flexible layer 240. In this embodiment, the another substrate 220 includes the polarizer 270 in place of the conductive pattern 250. The polarizer 270 may include polyimide or other suitable material.

Refer to FIG. 10, which illustrates a cross-sectional view of an electronic device 10I according to some embodiments of the present disclosure. The electronic device 10I includes the backlight module 260. The backlight module 260 may be disposed on the second surface S2 of the flexible layer 150. In this embodiment, the conductive pattern 140 may be disposed at the lower substrate, and the polarizer 270 may be disposed at the upper substrate. In some embodiments, the backlight module 260 may be disposed adjacent to the conductive pattern 140 and away from the polarizer 270.

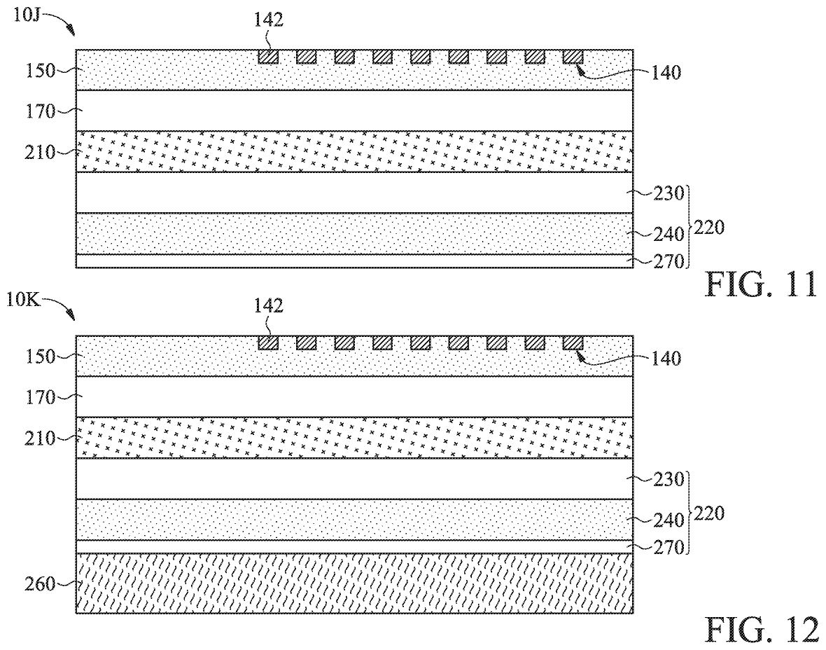

Refer to FIG. 11, which illustrates a cross-sectional view of an electronic device 10J according to some embodiments of the present disclosure. The conductive pattern 140 of the electronic device 10J is disposed at the upper substrate of the electronic device 10J, and the polarizer 270 is disposed at the lower substrate. In some embodiments, the conductive pattern 140 may be disposed at the upper substrate of the electronic device or the lower substrate of the electronic device, or both.

Refer to FIG. 12, which illustrates a cross-sectional view of an electronic device 10K according to some embodiments of the present disclosure. The electronic device 10K includes the backlight module 260. The backlight module 260 can be disposed away from the conductive pattern 140 and adjacent to the polarizer 270.

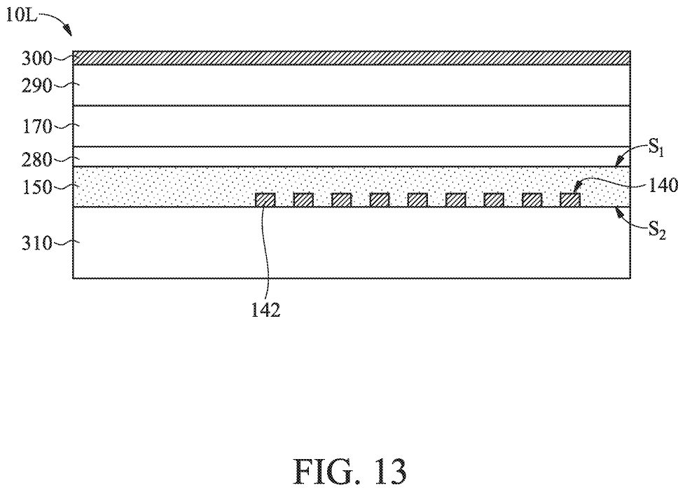

Refer to FIG. 13, which illustrates a cross-sectional view of an electronic device 10L according to some embodiments of the present disclosure. In some embodiments, the electronic device 10L includes a phase difference layer 280 disposed on the first surface S1 of the flexible layer 150. In some embodiments, the phase difference layer 280 may include a λ/4 plate or a λ/2 plate (λ is the wavelength of light). In some embodiments, the phase difference layer 280 may cause a phase difference, and the phase difference may be formed of a birefringence material such as a liquid-crystal material, a resin material, or the like.

In some embodiments, the electronic device 10L includes a light-emitting layer 290 disposed on the phase difference layer 280. In some embodiments, the light-emitting layer 290 includes an organic light-emitting diode or other suitable light-emitting elements. The light-emitting layer 290 may include an upper electrode, a lower electrode, and an organic light-emitting layer (not shown) disposed between the upper electrode and the lower electrode. The electronic device 10L includes a reflection layer 300. The reflection layer 300 can be used to reflect the light emitted by the light-emitting layer 290. The material of the reflection layer 300 may include a metal, such as molybdenum (Mo), titanium (Ti), copper (Cu), aluminum (Al), silver (Ag), tungsten (W), gold (Au), chromium (Cr), nickel (Ni), platinum (Pt), iridium (Ir), rhodium (Rh), indium (In), bismuth (Bi), an alloy thereof, but is not limited thereto.

In some embodiments, the electronic device 10L includes a substrate 310 that may be disposed on the second surface S2 of the flexible layer 150. The substrate 310 may include a plurality of active and/or passive elements. In this embodiment, the light-emitting layer 290 can be used as a light-emitting source such that the electronic device 10L can serve as a display device.

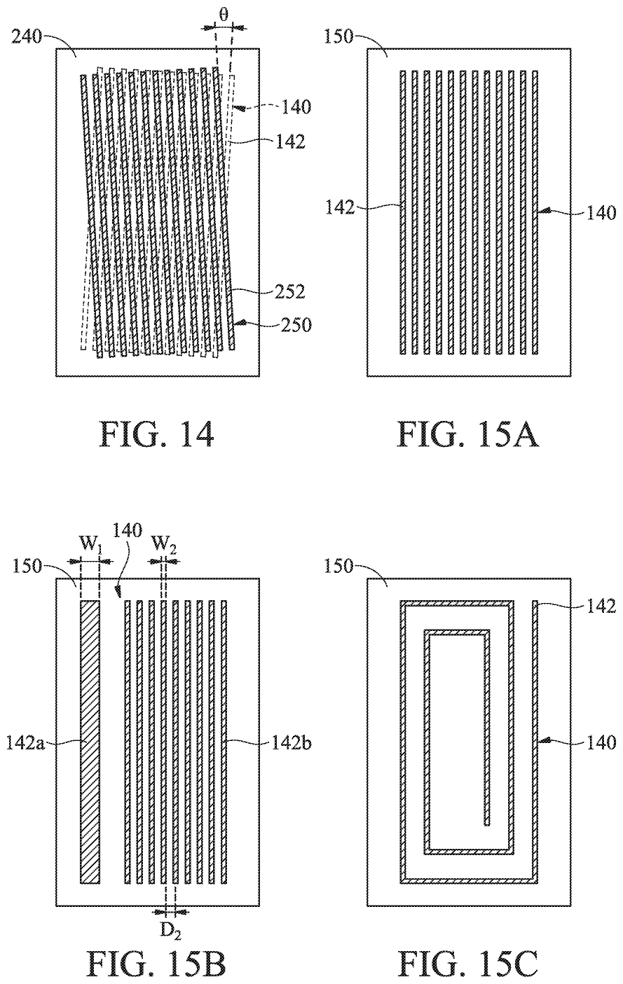

Refer to FIG. 14, which illustrates a top view of the conductive pattern 140 and the conductive pattern 250 according to some embodiments of the present disclosure. The angle formed by the extending direction of the metal line 142 (shown by a dashed line) of the conductive pattern 140 and the extending direction of the metal line 252 (shown by a solid line) of the conductive pattern 250 in the flexible layer 240 (or the flexible layer 150) is an angle θ. In some embodiments, the angle θ can be between 0° and 10° (0°≤0≤10°).

Refer to FIGS. 15A-15C, which illustrate different aspects of the conductive pattern 140 according to some embodiments of the present disclosure. The layout of the conductive pattern 140 can be designed as different shapes depending on the use of the electronic device. As shown in FIG. 15A, the conductive pattern 140 includes a plurality of metal lines 142, which may extend in the same direction.

As shown in FIG. 15B, the conductive pattern 140 includes a metal line 142a and a metal line 142b, and the metal line 142a and the metal line 142b may extend in the same direction. The metal line 142a may have a width W1, and the metal line 142b may have a width W2, wherein the width W1 refers to the maximum width in a direction perpendicular to the extending direction of the metal line 142a, and the width W2 refers to the maximum width in a direction perpendicular to the extending direction of the metal line 142b. In some embodiments, if the metal line 142a or the metal line 142b is a curved line, the width W1 or the width W2 may be defined depending on a partial line segment. After defining the extending direction of the partial line segment, the maximum width of the partial line segment is measured in a direction perpendicular to the extending direction. In some embodiments, the width W1 is greater than the width W2. The width W1 may be between 5 um and 50 um (5 um≤width W1≤50 um). The width W2 may be between 10 um and 1000 um (10 um≤width W2≤1000 um), or the width W2 may be between 10 nm and 100 nm (10 um≤width W2≤100 um), or the width W2 may be between 1 um and 100 um (1 um≤width W2≤100 um), but not limited thereto. In some embodiments, there may be a distance D2 between the two adjacent metal lines 142b, wherein the distance D2 refers to the minimum distance between two adjacent metal lines 142b. In some embodiments, the distance D2 may be in a range of 1 um to 1000 um (1 um≤distance D2≤1000 um), or the distance D2 may be in a range of 100 um to 1000 um (100 um≤distance D2≤1000 um), or distance D2 may be in a range of 50 nm to 200 nm (50 nm≤distance D2≤200 nm), but is not limited thereto. As shown in FIG. 15C, in some embodiments, the metal line 142 may have a spiral shape, and the spiral shape may be a clockwise direction and/or a counterclockwise direction, and the disclosure is not limited thereto. In some embodiments, the conductive pattern 140 may have various layouts. For example, in the first region of the display device, the conductive pattern 140 has the layout shown in FIG. 15A; in the second region of the display device, the conductive pattern 140 has the layout shown in FIG. 15B. In some embodiments, the metal lines 142 of the conductive pattern 140 may have various extending directions. For example, in the first region and the second region of the display device, the metal lines 142 may have different extending directions, but are not limited thereto.

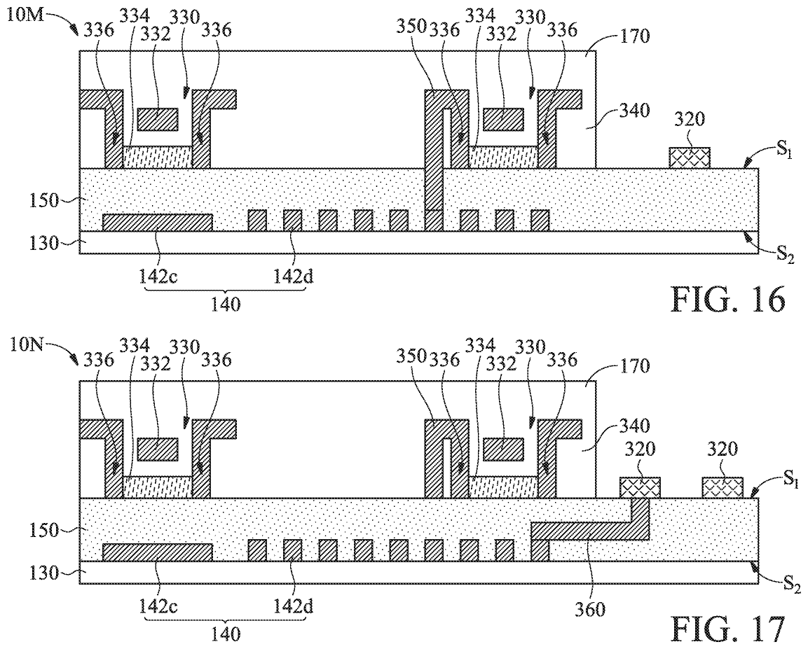

Refer to FIG. 16, which illustrates a cross-sectional view of an electronic device 10M according to some embodiments of the present disclosure. As shown in FIG. 16, the electronic device 10M includes a chip 320, which may be disposed on a portion of the first surface S1 of the flexible layer 150 that is not covered by the circuit layer 170. A plurality of thin film transistors 330 may be formed in the circuit layer 170 and separated by an insulation layer 340, but are not limited thereto.

The thin film transistor 330 includes a gate 332, a semiconductor layer 334, and a source/drain 336. The gate 332 may include a conductive material such as copper (Cu), aluminum (Al), molybdenum (Mo), tungsten (W), gold (Au), chromium (Cr), nickel (Ni), palladium (Pt), titanium (Ti), but is not limited thereto. The semiconductor layer 334 may be amorphous silicon, polysilicon, low temperature polysilicon, metal oxide or other materials. The metal oxide includes indium gallium zinc oxide (IGZO), indium zinc oxide (IZO), or indium gallium zinc tin oxide (IGZTO), but is not limited thereto. In some embodiments, the electronic device 10M may include the thin film transistor 330 having the foregoing different semiconductor layers 334. For example, some of the thin film transistors 330 include a semiconductor layer 334 of indium gallium zinc oxide, and some of the thin film transistors 330 include a semiconductor layer of low temperature polysilicon 334, but are not limited thereto. The material of the source/drain 336 may be the same as or similar to that of the gate 332 and will not be repeated herein. The insulation layer 340 may include silicon oxide, silicon nitride, silicon oxynitride, but is not limited thereto.

The thin film transistor 330 can be formed by a deposition process, a lithography process, and an etching process. The deposition process includes, but is not limited to, a physical vapor deposition process, a chemical vapor deposition process, and an atomic layer deposition process. The lithography process includes photoresist coating (e.g., spin-coating), soft baking, photomask alignment, exposure, post-exposure baking, developing a photoresist, rinsing, drying (e.g., hard baking), other suitable processes, or a combination thereof. In addition, the lithography process can be performed or replaced by other suitable methods, such as maskless lithography, electron-beam writing, and ion-beam writing. The etching process includes dry etching, wet etching, or other etching methods, and is not limited thereto.

In some embodiments, the conductive pattern 140 may include a metal line 142c and a metal line 142d. The metal line 142c and the metal line 142d may have different widths. The metal line 142c may be disposed under the thin film transistor 330 as a light-shielding layer to reduce light irradiating the semiconductor layer 334. The metal line 142d may be electrically connected to the thin film transistor 330 via a wire 350.

Refer to FIG. 17, which illustrates a cross-sectional view of an electronic device 10N according to some embodiments of the present disclosure. The electronic device 10N includes a plurality of chips 320 disposed on the first surface S1 of the flexible layer 150; and at least one chip 320 may be electrically connected to the conductive pattern 140 via wires 360 disposed in the flexible layer 150.

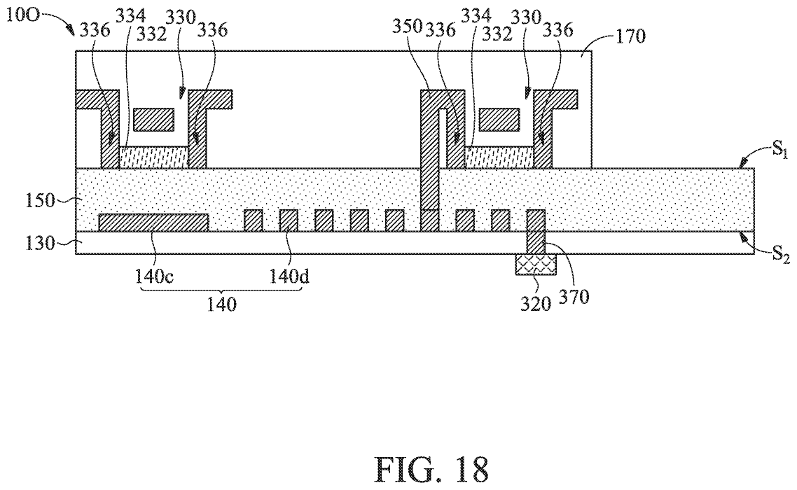

Refer to FIG. 18, which illustrates a cross-sectional view of an electronic device 10O according to some embodiments of the present disclosure. The chip 320 of the electronic device 10O may be disposed on the second surface S2 of the flexible layer 150 and electrically connected to the conductive pattern 140 via a wire 370 disposed in the protection layer 130.

In some embodiments of the present disclosure, a conductive pattern is first disposed on a dummy substrate, and then a flexible layer and a circuit layer are formed to form an electronic device. The foregoing method may form a conductive pattern on a flexible substrate by a Nanoimprint Lithography. In some embodiments, the flexible layer can be bent and the chip is disposed on the surface of the flexible layer. In some embodiments, the electronic device may have a medium layer that can be sealed between the flexible layer and the another substrate. In some embodiments, the another substrate may also have a flexible layer and a conductive pattern. In some embodiments, the conductive pattern may be disposed at the upper substrate of the electronic device, the lower substrate of the electronic device, or both. In some embodiments, the conductive pattern may have different layouts and/or shapes and may serve as a light polarizing element, an antenna element, a touch sensing element, and/or a fingerprint sensing element. In some embodiments, the conductive pattern is embedded into the flexible layer.

The thickness can be measured using an optical microscopy (OM), scanning electron microscope (SEM), a film thickness profiler (α-step), an elliptical thickness gauge, or other suitable method. To be specific, in some embodiments, after removing the medium layer 210, a cross-sectional image of the structure is taken using a scanning electron optical microscope, and the maximum thickness in the cross-sectional image is measured. The maximum thickness described above may be the maximum thickness in any of the cross-sectional images. In other words, it may be the maximum thickness in a partial region of the liquid-crystal device.

Although some embodiments of the present disclosure and their advantages have been described in detail, it should be understood that various changes, substitutions and alterations can be made by any person skilled in the art without departing from the spirit and scope of the disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. In addition, each of the claims comprises an individual embodiment, and the scope of the disclosure also includes each of the claims and the combinations of the individual embodiment of the claims. The features of the various embodiments can be arbitrarily mixed and used as long as they do not depart from or conflict with the spirit of the disclosure.

1. A manufacturing method of an electronic device comprising:
providing a dummy substrate;
forming a conductive pattern on the dummy substrate;
forming a flexible layer covering the conductive pattern;
forming a circuit layer on the flexible layer; and
removing the dummy substrate.

2. A manufacturing method of an electronic device according to claim 1, wherein the process of forming the flexible layer comprises:
disposing a polymer layer which is in a liquid state covering the conductive pattern and then solidifying the polymer layer to form the flexible layer so that the conductive pattern is embedded into the flexible layer.

3. A manufacturing method of an electronic device according to claim 1, further comprising:
forming a protective layer on the dummy substrate before forming the conductive pattern on the dummy substrate.

4. A manufacturing method of an electronic device according to claim 1, wherein the conductive pattern performs at least one of functions of a light polarizing element, an antenna element, a touch sensing element and a fingerprint sensing element.

5. A manufacturing method of an electronic device according to claim 1, further comprising:
providing an another substrate; and
sealing a liquid crystal layer between the flexible layer and the another substrate.

6. An electronic device comprising:
a flexible layer having a first surface and a second surface opposed to the first surface;
a circuit layer on the first surface of the flexible layer; and
a conductive pattern, wherein the flexible layer is between the circuit layer and the conductive pattern.

7. An electronic device according to claim 6, wherein the conductive pattern is embedded into the flexible layer from the second surface of the flexible layer.

8. An electronic device according to claim 7, further comprising a protective layer covering the conductive pattern and the second surface of the flexible layer.

9. An electronic device according to claim 6, wherein the flexible layer has a curved shape.

10. An electronic device according to claim 9, further comprising:
an another substrate of curved shape, and
a liquid crystal layer sealed between the flexible layer and the another substrate.
